(19) United States
(12) Patent Application Publication
(10) Pub. No.: US 2017/0329439 A1
(43) Pub. Date: Nov. 16, 2017

(54) INPUT UNIT AND ELECTRONIC DEVICE HAVING THE SAME

(71) Applicant: Samsung Electronics Co., Ltd., Gyeonggi-do (KR)

(72) Inventors: Jeongsik JEONG, Gyeonggi-do (KR); Joohoon LEE, Gyeonggi-do (KR); Eunsung CHO, Gyeonggi-do (KR); Yongsang YUN, Gyeonggi-do (KR)

(73) Assignee: Samsung Electronics Co., Ltd.

(21) Appl. No.: 15/592,769

(22) Filed: May 11, 2017

(30) Foreign Application Priority Data
May 11, 2016 (KR) 10-2016-0057755

(51) Int. Cl. G06F 3/044; H01L 27/32

(52) U.S. Cl. CPC G06F 3/044; G06F 2203/04105; H01L 27/323

(57) ABSTRACT

Disclosed is an input unit of an electronic device, including a first pattern layer formed of electrodes for detecting a first direction input value, a conductive layer disposed above the first pattern layer and separated from the first pattern layer, and a second pattern layer disposed above the conductive layer and separated from the conductive layer, the second pattern layer including patterns for detecting a second direction input value and a third direction input value, wherein the conductive layer is configured to absorb a portion of a magnetic flux generated by one of the electrodes or the second pattern layer, for detecting a distance change from the first pattern layer.

### PRIORITY

This application claims priority under 35 U.S.C. §119(a) to a Korean Patent Application filed in the Korean Intellectual Property Office on May 11, 2016 and assigned Serial No. 10-2016-0057755, the contents of which are incorporated herein by reference.

### BACKGROUND

### 1. Field of the Disclosure

The present disclosure relates generally to an electronic device, and more particularly, to an input unit and an electronic device having the same.

### 2. Description of the Related Art

With the recent increases in the integrity of electronic devices and the development of advanced technologies, various functions have been introduced into electronic devices, such as a touch screen used as a main input unit. Such an electronic device can display a digital image on a computer screen corresponding to a cursor movement if a picture is drawn with a finger or a touch pen. The electronic device reads X-axis and Y-axis coordinates on a matrix, converts the location information of the user input into a digital format, and provides various applications and conveniences for graphic works.

In order to change the thickness of a character, it has conventionally been necessary in an electronic device to have a pen pressure detecting function for detecting a pressure force as well as a digitizer input unit that recognizes location information (X- and Y-coordinates) of an input. In order to provide the pen pressure detecting function, the electronic device is configured with a structure in which a separate pressure sensor, digitizer input unit, and pressure sensor are stacked. However, this configuration is problematic in that the thickness of the electronic device is increased, resulting in a less compact electronic device having elevated manufacturing costs.

As such, there in a need in the art for a more cost-effective and compact input unit for an electronic device.

### SUMMARY

The present disclosure has been made to address the above-mentioned shortcomings in the art and to provide the advantages described below.

Accordingly, an aspect of the present disclosure is to provide an input device and an electronic device that can share a portion of a digitizer structure and a portion of a pressure sensor structure configured in the input unit, and the electronic device that can simultaneously provide a digitizer function and a pressure sensor function.

According to an aspect of the present disclosure, an electronic device may include a first pattern layer formed of electrodes for detecting a first direction input value, a conductive layer disposed above the first pattern layer and separated from the first pattern layer, and a second pattern layer disposed above the conductive layer and separated from the conductive layer, the second pattern layer including patterns for detecting a second direction input value and a third direction input value, wherein the conductive layer is configured to absorb a portion of a magnetic flux generated by one of the electrodes or the second pattern layer, for detecting a distance change from the first pattern layer.

According to another aspect of the present disclosure, an electronic device may include a first pattern layer formed of electrodes for detecting a first direction input value, at least one second pattern layer disposed above the conductive layer and separated from the conductive layer, the second pattern layer configured to detect a second direction input value and a third direction input value, a conductive layer disposed between the first pattern layer and the at least one second pattern layer, and a first input detecting unit electrically connected to the first pattern layer and a second input detecting unit electrically connected to the at least one second pattern layer.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 illustrates a structure of a multi-input pad in an input unit according to embodiments of the present disclosure;

FIGS. 2A, 2B and 2C illustrate a multi-input layer according to embodiments of the present disclosure;

FIG. 3 illustrates a structure of an input unit according to embodiments of the present disclosure;

FIG. 4 illustrates a configuration of an electronic device according to embodiments of the present disclosure;

FIG. 5 illustrates a network configuration of an electronic device according to embodiments of the present disclosure;

FIG. 6 illustrates a configuration of an electronic device according to embodiments of the present disclosure; and

FIG. 7 illustrates a configuration of a program module according to embodiments of the present disclosure.

### DETAILED DESCRIPTION

The following description with reference to the accompanying drawings is provided to assist in a comprehensive understanding of embodiments of the present disclosure. It includes various details to assist in that understanding, but those of ordinary skill in the art will recognize that various changes and modifications of the embodiments described herein can be made without departing from the spirit and scope of the present disclosure. In addition, descriptions of well-known functions and constructions may be omitted for the sake of clarity and conciseness.

The terms and words used in the following description and claims are not limited to their dictionary meanings, but are merely used to enable a clear and consistent understanding of the present disclosure. Accordingly, it should be apparent to those skilled in the art that the following description of embodiments of the present disclosure is provided for illustration purposes only, and not for the purpose of limiting the present disclosure as defined by the appended claims and their equivalents.

It is to be understood that the singular forms “a”, “an”, and “the”, also include plural forms unless the context clearly dictates otherwise. Thus, reference to “a component surface” includes reference to one or more component surfaces.

Expressions such as “include” and “may include” which may be used in the present disclosure denote the presence of the disclosed functions, operations, and elements, and do not limit one or more additional functions, operations, and elements. In the present disclosure, terms such as “include” and/or “have”, may be construed to denote a certain characteristic, number, operation, element, component or a combination thereof, but should not be construed to exclude the existence of or a possibility of the addition of one or more other characteristics, numbers, operations, elements, components or combinations thereof.

In the present disclosure, the expression “and/or” includes any and all combinations of the associated listed words. For example, the expression “A and/or B” may include A, B, or both A and B.

In the present disclosure, expressions including ordinal numbers, such as “first” and “second”, may modify various elements, but such elements are not limited by the above expressions. For example, the above expressions do not limit the sequence and/or importance of the elements, and are used merely for the purpose of distinguishing an element from the other elements. For example, a first user device and a second user device indicate different user devices, although both are user devices. A first element could be referred to as a second element, and similarly, a second element could also be referred to as a first element without departing from the scope of the present disclosure.

When a component is referred to as being “connected” or “accessed” to another component, it should be understood that not only is the component connected or accessed to the other component, but also another component may exist between the component and the other component. When a component is referred to as being “directly connected” or “directly accessed” to another component, it should be understood that there is no component between the component and the another component.

Unless otherwise defined, all terms including technical and/or scientific terms used herein have the same meaning as commonly understood by one of ordinary skill in the art to which the present disclosure pertains. In addition, unless otherwise defined, all terms defined in generally used dictionaries may not be overly interpreted.

The electronic device corresponds to at least one of a smartphone, a tablet personal computer (PC), a mobile phone, a video phone, an e-book reader, a desktop PC, a laptop PC, a netbook computer, a personal digital assistant (PDA), a portable multimedia player (PMP), a digital audio player (e.g., moving picture experts group phase 1 or phase 2 (MPEG-1 or MPEG-2) audio layer 3 (MP3) player), a mobile medical device, a camera, and a wearable device such as a head-mounted-device (HIVID) (e.g., electronic eyeglasses), electronic clothing, an electronic bracelet, an electronic necklace, an appcessory, an electronic tattoo, or a smart watch.

The electronic device according to the embodiments of the present disclosure may also be smart home appliances. Examples of the smart home appliances include a television (TV), a digital video versatile disc (DVD) player, an audio system, a refrigerator, an air-conditioner, a cleaning device, an oven, a microwave oven, a washing machine, an air cleaner, a set-top box, a TV box (e.g., Samsung HomeSync™, Apple TV′, or Google TV™), a game console, an electronic dictionary, an electronic key, a camcorder, an electronic album, or the like.

The electronic device according to the embodiments of the present disclosure may also include medical devices (e.g., magnetic resonance angiography (MRA), magnetic resonance imaging (MM), computed tomography (CT), a scanning machine, or an ultrasonic scanning device), a navigation device, a global positioning system (GPS) receiver, an event data recorder (EDR), a flight data recorder (FDR), a vehicle infotainment device, an electronic equipment for ships (e.g., navigation equipment, gyrocompass), avionics, a security device, a head unit for vehicles, an industrial or home robot, an automated teller machine (ATM), or a point of sales (POS) system.

The electronic device according to the embodiments of the present disclosure may also include furniture or a portion of a building/structure, an electronic board, an electronic signature receiving device, a projector, and various measuring instruments, such as a water, electric, gas and wave meter. The electronic device may also include a combination of the devices listed above, and may be a flexible and/or contoured device. The electronic device is not limited to the aforementioned devices.

Hereinafter, electronic devices according to embodiments of the present disclosure will be described in detail with reference to the accompanying drawings. In the description, the term ‘user’ may refer to a person or a device that uses or otherwise controls the electronic device, such as an artificial intelligence electronic device.

An input unit and an electronic device having the same according to embodiments of the present disclosure are formed in a digitizer structure such that a metallic layer for removing a magnetic flux imbalance of an electromagnetic field is used as one of two electrodes for a pressure sensor, and thus, the size and material costs of an electronic device can be reduced by limiting the thickness of the input unit.

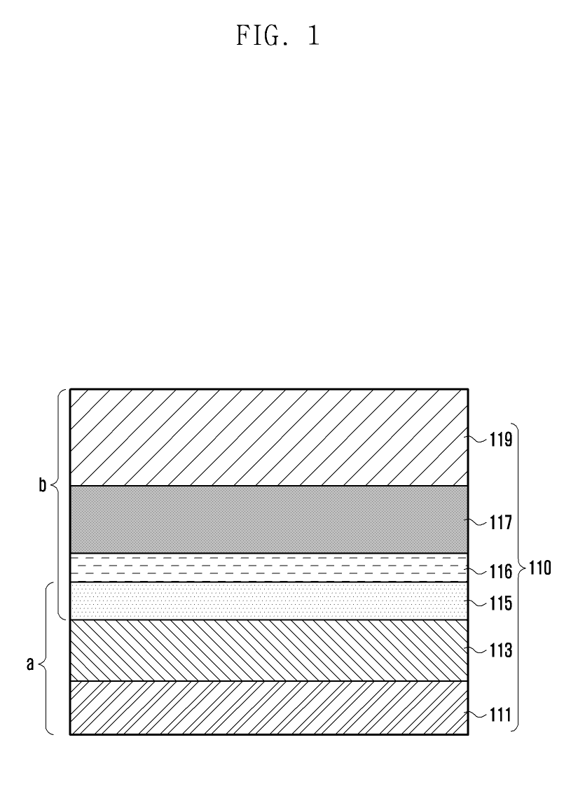

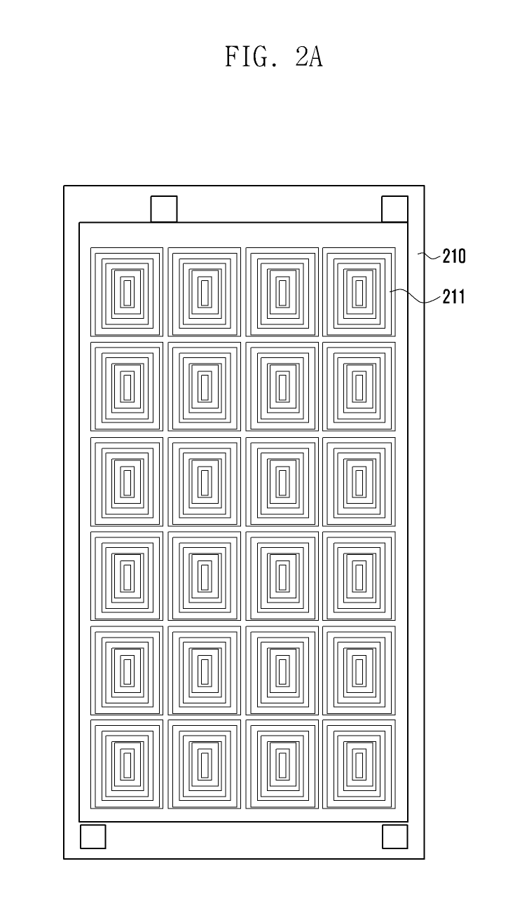

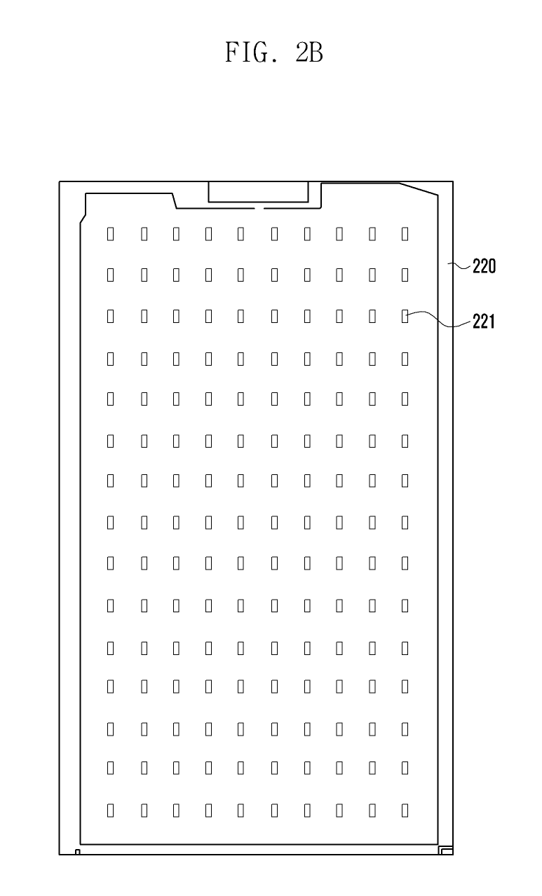

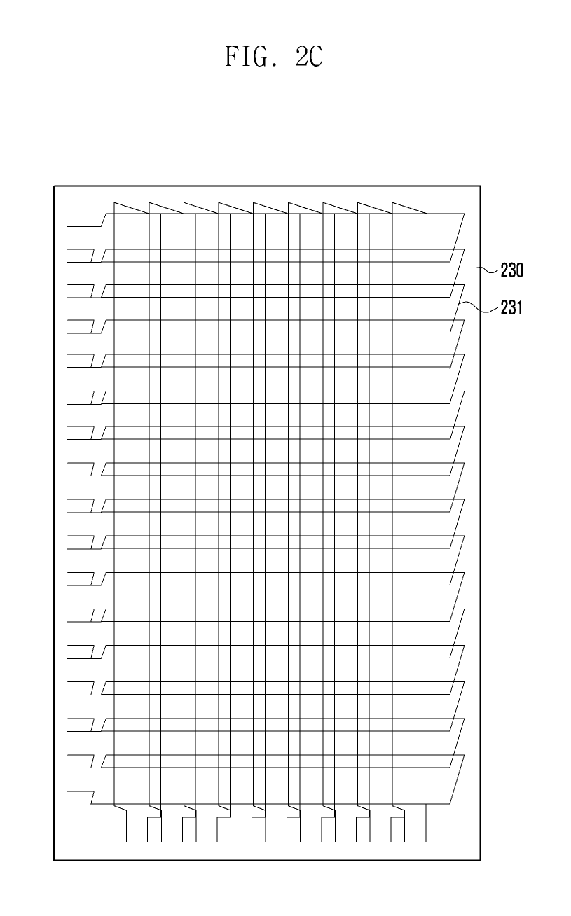

FIG. 1 illustrates a structure of a multi-input pad in an input unit according to embodiments of the present disclosure. FIGS. 2A, 2B and 2C illustrate a multi-input layer according to embodiments of the present disclosure.

With reference to FIG. 1, the input unit 110 according to an embodiment of the present disclosure may include a sensor layer for a first sensor detection and a multi-sensor pad configured by stacking sensor layers for a second sensor detection. For example, the first sensor may be a pressure sensor for detecting a pressure change, and the second sensor may be a sensor for recognizing X- and Y-coordinates, such as an electromagnetic induction input sensor or a touch sensor. However, the present disclosure is not limited to these example.

The input unit according to an embodiment of the present disclosure may include a first pattern layer 111 electrically connected to the first sensor (device or circuit), a dielectric layer 113, a conductive layer 115, a magnetic layer 117, and a second pattern layer 119 electrically connected to the second sensor (device or circuit). The conductive layer 115 can be electrically connected to the first sensor and the second sensor. The first pattern layer 111 and the second pattern layer 119 may include a plurality of layers.

According to an embodiment of the present disclosure, the input unit 110 may be configured in a stacked structure of a first pattern layer 111 formed of patterns for detecting a pressure, a dielectric layer 113, a conductive layer 115, a magnetic layer 117, and a second pattern layer 119 formed of a pattern or a coil for detecting an electromagnetic induction input. The second pattern layer 119 may be configured by stacking a pattern layer for recognizing an X-coordinate and a pattern layer for recognizing a Y-coordinate.

The input unit 110 may further include an adhesive layer 116 stacked between the conductive layer 115 and the magnetic layer 117.

In the input unit 110, the first pattern layer 111, the dielectric layer 113, and the conductive layer 115 may be used as a first sensor (a) for detecting a capacitance change according to a pressure change, and the conductive layer 115, the magnetic layer 117, and the second pattern layer 119 may be used as a second sensor (b) for detecting a voltage change according to an electromagnetic induction.

According to an embodiment of the present disclosure, the first pattern layer 111 may be a circuit 210 printed with a conductive electrode 211 into which a pressure change is electrically input, as illustrated in FIG. 2A. For example, the conductive electrode 211 may be formed of a conductive material such as aluminum and copper and may include a plurality of patterns so that generation of a pressure change can be detected at any location. Rectangular patterns are configured with electrodes having different sizes and disposed in a 4×6 arrangement as shown in FIG. 2A; however, the present disclosure is not limited to this example, and the patterns may be disposed in various forms such as a circular pattern.

The distance between the first pattern layer 111 and the conductive layer 115 changes according to an external pressure, and the two layers can be used as electrodes for detecting a capacitance change according to a distance change. A dielectric layer 113 can be stacked on the first pattern layer 111 so that the first pattern layer 111 and the conductive layer 115 are displaced by maintaining a predetermined distance.

The dielectric layer 113 can be formed on the first pattern layer 111 so that the first pattern layer 111 and the conductive layer 115 are displaced by maintaining a predetermined distance. The dielectric layer 113 may be configured with a material having a dielectric property such as SiO₂, and with an air gap or a material having a different dielectric constant from the first pattern layer 111 or the conductive layer 115. With reference to the conductive layer 115 or conductive sheet 220 shown in FIG. 2B, the dielectric layer 113 can be formed so that a part 221 of the conductive sheet 220 is removed and exposed.

The conductive layer 115 is formed on the upper side of the dielectric layer 113 and may be a metal sheet having a conductive property, such as a copper sheet. The conductive layer 115 can be formed as a ground layer of a pressure sensor circuit (or device) for detecting a capacitance change.

According to an embodiment of the present disclosure, the conductive layer 115 elastically deforms or restores according to a pressure applied to the upper part of the input unit 110, and the distance to the first pattern layer 111 can change. If so, a capacitance changes according to the distance change between the second pattern layer 111 and the conductive layer 115, and the input unit 110 can detect a pressure change through the capacitance change.

According to an embodiment of the present disclosure, the conductive layer 115 can remove a magnetic imbalance generated at a part of a magnetic layer 117 by absorbing a magnetic flux passing through the magnetic layer 117 if electromagnetic power is induced.

The magnetic layer 117 is formed on the conductive layer 115 and may be a magnetic sheet for inducing an electromagnetic field of the second pattern layer 119. The magnetic layer 117 can be configured with magnetic materials including at least one of iron (Fe), nickel (Ni), zinc (Zn), manganese (Mn), magnesium (Mg), cobalt (Co), barium (Ba), and strontium (Sr).

According to an embodiment of the present disclosure, as shown in FIG. 2C, the second pattern layer 119 may be an electromagnetic resonance (EMR) sensor board 230 configured with a plurality of coils 231 for detecting a location of a magnetic field according to an approach of an electronic pen in an electromagnetic method. The coil 231 may be formed of one of copper (Cu), aluminum (Al), gold (Au), silver (Ag), titanium (Ti), palladium (Pd), chromium (Cr), or any suitable combination thereof, and may have a matrix structure having X-axis and Y-axis directions for measuring the location of the electronic pen.

According to another embodiment of the present disclosure, the second pattern layer 119 may include a coil unit configured in a matrix structure by applying a screen print method to a flexible printed circuit board (FPCB) or a transparent board.

According to another embodiment of the present disclosure, the second pattern layer 119 can be formed in a structure in which a set of loop coils having a rectangular shape are arranged overlapping each other in a horizontal direction [and another set of loop coils are arranged overlapping each other in a vertical direction.

In the input unit 110 according to embodiments of the present disclosure, among 2 electrodes for detecting a pressure, an upper electrode (i.e., the conductive layer 115) is configured as a ground layer; and the magnetic layer 117 and the second pattern layer 119 for detecting an electromagnetic induction input are formed by being stacked onto the conductive layer 115. Accordingly, the conductive layer 115 can be used as an electrode for detecting a pressure or absorbing a magnetic flux passing though the magnetic layer 117 if electromagnetic power is generated.

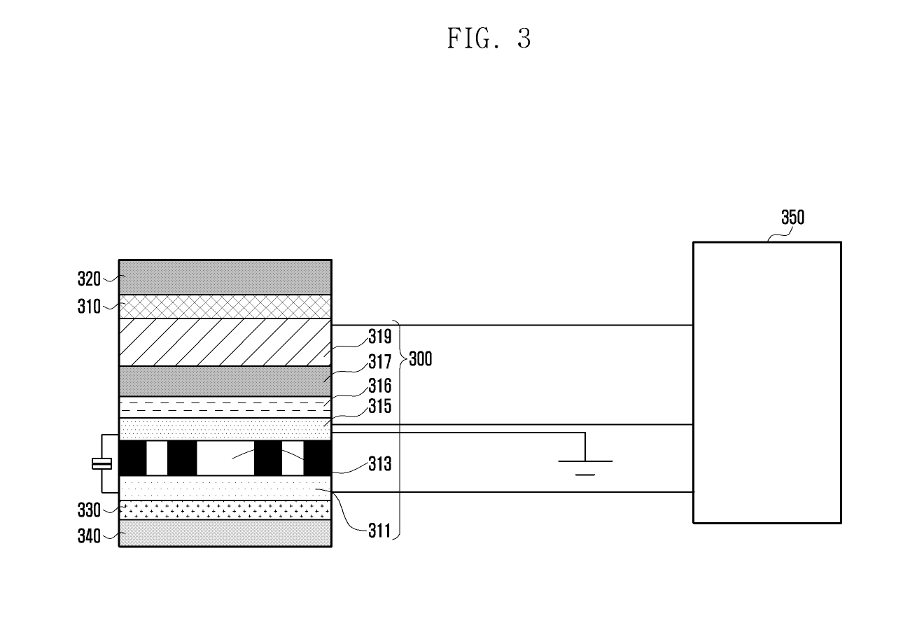

FIG. 3 illustrates a structure of an input unit according to embodiments of the present disclosure.

With reference to FIG. 3, the input unit may include a multi-sensor pad 300, display panel 310, touch panel 320, and sensor circuit (or input detecting unit) 350.

The multi-sensor pad 300 may have a stacked structure of a first pattern layer 311 formed of patterns for detecting a first sensor detection, dielectric layer 313, conductive layer 315, adhesive layer 316, magnetic layer 317, and second pattern layer 319 formed of patterns (or coils) for detecting a second sensor detection, as illustrated in FIG. 1. For example, the first sensor may be a pressure sensor for detecting a pressure change, and the second sensor may be an electromagnetic induction input sensor or a touch sensor for recognizing X- and Y-coordinates. According to an embodiment of the present disclosure, the first pattern layer 311 may be a board printed with a conductive pattern into which a pressure change is electrically input, can measure a capacitance change from a distance change of the conductive layer 315 according to an external pressure, and can be electrically connected to a sensor circuit (IC) 350 for calculating at least one of a pressure value (Z-coordinate) and a location value (X- and Y-coordinates).

The conductive layer 315 may be formed of a metal sheet having a conductive property on the dielectric layer 313, and may be formed as a ground layer of the sensor circuit 350 for detecting a capacitance change. Conductive electrodes included in the first pattern layer 311 and the conductive layer 315 are displaced to maintain a predetermined distance by the dielectric layer 313, and can be used as two electrodes for accumulating an electric charge. For example, if the conductive layer 315 deforms or restores elastically according to a pressure applied to the upper part of the input unit, the distance to the first pattern layer 311 changes accordingly. If a capacitance amount accumulated between the two layers also changes, the input unit can detect a pressure change through the capacitance change.

The conductive layer 315 can remove magnetic imbalance generated at a part of the magnetic layer 317 by absorbing a magnetic flux passing through the magnetic layer 317 if electromagnetic power is induced.

The conductive layer 315 can be electrically connected to the sensor circuit 350. For example, the sensor circuit 350 supplies a reference voltage so that a capacitance change of the first pattern layer 311 and an induced electromagnetic power change of the second pattern layer 319 can be detected through the conductive layer 315.

According to an embodiment of the present disclosure, the sensor circuit 350 may include a first sensor electrically connected to the first pattern layer 311 and a second sensor electrically connected to the second pattern layer 319.

The sensor circuit 350 supplies a reference voltage to the conductive layer 315 for detecting a pressure value and calculates the pressure value by measuring a signal transmitted from the first pattern layer 311. The sensor circuit 350 supplies a reference voltage to the conductive layer 315 for detecting an electromagnetic induction input and calculates a location value of the electromagnetic induction input by measuring a signal transmitted from the second pattern layer 319.

The sensor circuit 350 is connected to a conductive pattern of the first pattern layer 311, and can measure an electric current amount output by the conductive pattern and calculate a pressure value (Z-coordinate) based on the measured electric current amount. The sensor circuit 350 can calculate a location value (X- and Y-coordinates) of the conductive pattern where a capacitance change is generated. For example, rectangular patterns configured with electrodes having different sizes are disposed on a board as shown in FIG. 2A, and if a capacitance of a rectangular pattern disposed at a specific location changes according to a pressure, the first pattern layer 311 can measure a location value (X- and Y-coordinates) of the rectangular pattern by identifying the location of the rectangular pattern. The second pattern layer 319 may be an EMR sensor board configured with a plurality of coils disposed in a matrix form so that a location of a magnetic field can be detected according to an approach of an electric pen integrated with a metal coil.

The input unit according to an embodiment of the present disclosure may be configured with a sensor circuit (input detecting unit) 350 as shown in FIG. 3; however, the present disclosure is not limited to this example, and the input unit may be configured separately with a first sensor circuit electrically connected to the first pattern layer 311 and a second sensor circuit electrically connected to the second pattern layer 319. In this case, at least one of the first sensor circuit and the second sensor circuit can be electrically connected to the conductive layer 315 in order to supply a reference voltage for sensing.

The second pattern layer 319 can be electrically connected to a drive coil receiving electric current and a sensor circuit 350 for detecting a voltage difference according to an induced electromagnetic power and for calculating a location value (X−1 and Y−1 coordinates) of an electromagnetic induction input. For example, the second pattern layer 319 can be connected to an electromagnetic input sensor circuit included in the sensor circuit 350.

If an alternative current is supplied to coils of the second pattern layer 319 in the input unit, a magnetic field is formed at the second pattern layer 319 and the magnetic layer 317. If an electric pen integrated with a metal coil approaches the input unit, an alternative magnetic field is generated according to a metal induced voltage of the electronic pen, and a voltage difference is generated according to a change of the electromagnetic field. The input unit measures the voltage difference through the electromagnetic input sensor circuit connected to the second pattern layer 319, and measures location information of the electronic pen, i.e., location value (X−1 and Y−1 coordinates) of the electromagnetic induction input.

For example, the display panel 310 may be formed of one of a liquid crystal display (LCD), a light-emitting diode (LED) display, an organic light-emitting diode (OLED) display, a micro electro mechanical system (MEMS) display, or electronic paper display. The display panel 330 can display various contents to a user, such as a text, image, video, icon, or symbol. Alternatively, the display panel 330 can display a screen related to an operation state of the input unit.

The touch panel 320 is stacked on the multi-sensor pad 300 and can be formed in a corresponding structure according to a resistive, capacitive, or infrared type.

According to an embodiment of the present disclosure, a touch panel of a resistive type may have a stacked structure of a spacer for maintaining a distance between two boards coated with a transparent electrode layer. A signal for detecting a location is generated if a finger or a pen contacts the upper board of the two boards, and the touch panel of the resistive type can determine the location by detecting an electric signal from the lower board.

According to another embodiment of the present disclosure, a touch panel of a capacitive type may have a structure formed of a transparent electrode by coating a special conductive metal on both surfaces of a board configuring a touch screen sensor. The touch panel of the capacitive type can detect a location by supplying a certain amount of an electric current to a conductive metal. If a finger touches or approaches to the upper surface of the input unit, the touch panel can detect a capacitance change, and can detect a touch location by calculating the amount of the electric current.

According to another embodiment of the present disclosure, a touch panel of an infrared type may have a structure whereby light receiving elements changing a resistance value according to light generated from a light emitting diode are disposed facing each other at the circumference of the panel. If a finger touches a screen, the touch panel of the infrared type can detect a location by measuring a change of a resistance value generated at a part of the screen covered by the finger.

The touch panel 320 may further include a structure connected to a touch input circuit for calculating a location value (X−2 and Y−2 coordinates) of a touch input. For example, if a user's finger or a pen touches a screen, a capacitance changes in the touch panel 320, and the input unit can detect a location of a signal according to the change of capacitance.

The input unit may further include a heat dissipation sheet 330 and a bracket 340 under the multi-sensor pad 300. The heat dissipation sheet 330 may be formed of a material having a high heat conductivity so that heat generated from an input unit or an electronic device can be dissipated efficiently to the outside and electromagnetic waves generated by other components of the input unit or the electronic device can be blocked. The bracket 340 supports the above structures by surrounding the structures. The bracket 340 can be configured with a non-magnetic metal such as magnesium, aluminum, or non-magnetic stainless steel.

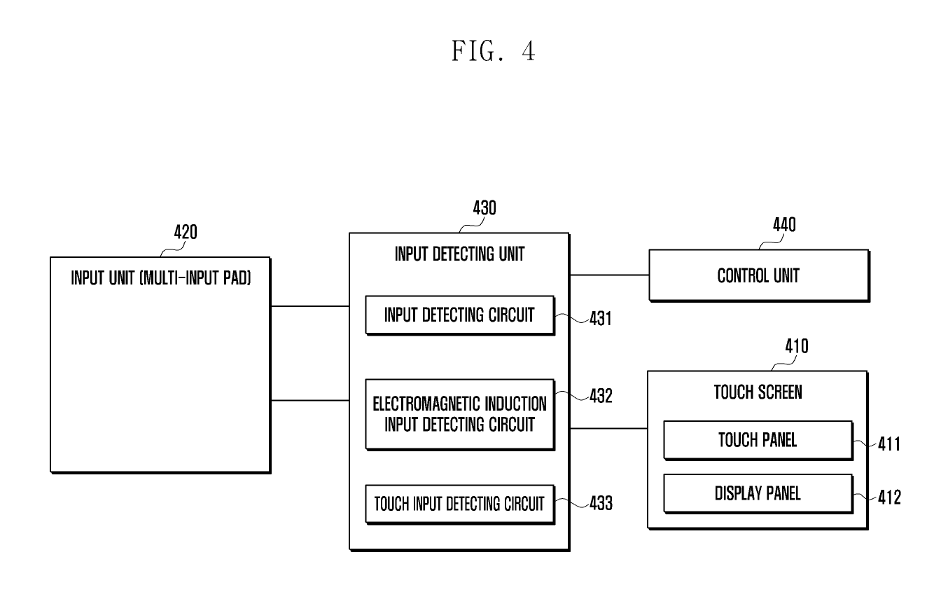

FIG. 4 illustrates a configuration of an electronic device according to embodiments of the present disclosure.

With reference to FIG. 4, the electronic device may include a touch screen 410, input unit (multi-input pad) 420, input detecting unit (input detecting module) 430, and control unit 440.

The touch screen 410 may include a touch panel 411 and a display panel 412 for a user interaction with the electronic device. The touch panel 411 can measure a location value (X−2 and Y−2 coordinates) of a touch input by identifying a touch point and transmitting a touch input signal to a touch input detecting circuit 433 in response to a user's touch input information (e.g., touch or proximity). The touch panel 411 can be configured as an add-on type located on the display panel 412, or as an on-cell or in-cell type inserted in the display panel 412. The touch screen 410 can be disposed on the upper side of the input unit 420.

The touch panel 411 can detect at least one of a single touch, proximity touch, and multi-touch from the touch screen 410.

The display panel 412 displays image data received from a control unit 440 by converting the image data to an analog signal under the control of the control unit 440. The display panel 412 can be configured in a flat display panel such as an LCD, OLED, and AMOLED.

The electronic device according to an embodiment of the present disclosure can be formed in a structure whereby the touch screen is stacked on the input unit.

The input unit 420 may include a multi-input pad configured by stacking a first pattern layer 111 formed of patterns for detecting a pressure, dielectric layer 113, conductive layer 115, magnetic layer 117, and second pattern layer 119 formed of patterns or coils for detecting an electromagnetic induction input, as shown in FIG. 1. Detailed descriptions on the input unit 420 will be omitted here since the input unit 420 has the same structure as the input unit 110 of FIG. 1.

The input unit 420 can detect a pressure applied to the upper part of the input unit 420 and a pen input generated by an electromagnetic induction and a touch input, and can transmit the detected pressures to the input detecting unit 430 by converting the pressures to electric signals.

The input detecting unit 430 is electrically connected to the input unit (multi-input pad) 420 and the touch screen 410, can measure at least one of a pressure, location information of electromagnetic induction input and touch input, and a pressure value, and can transmit the measured input data to the control unit 440.

The input detecting unit 430 may include at least one of a pressure detecting circuit 431, electromagnetic induction input detecting circuit 432, and touch input detecting circuit 433, which can be configured in an integrated chip (IC) or an IC package or can be configured in separate ICs.

The pressure detecting circuit 431 can be electrically connected to the first pattern layer and the conductive layer, can supply a reference voltage through the conductive layer for a detection of a capacitance change, and can receive a capacitance signal from the first pattern layer according to a pressure. For example, the pressure detecting circuit 431 measures a signal transmitted from the first pattern layer. If the conductive layer of FIG. 1 deforms, the pressure detecting circuit 431 can identify a capacitance change according to a distance change and measure at least one of a pressure value (Z-coordinate) corresponding to the capacitance change and a location value (X- and Y-coordinates) that indicates a location of a pressure applied to the multi-panel pad. The pressure detecting circuit 431 can transmit input data including at least one of the measured pressure value (Z-coordinate) and the pressure location value (X- and Y-coordinates) to the control unit 440.

According to an embodiment of the present disclosure, the electromagnetic induction input detecting circuit 432 can be electrically connected to the second pattern layer and the conductive layer of FIG. 1, can supply a reference voltage through the conductive layer for a detection of electromagnetic induction, and can receive an electromagnetic force generation signal from the second pattern layer. For example, the electromagnetic induction input detecting circuit 432 can identify a generation of voltage difference according to the induced electromagnetic force by measuring a signal transmitted from the second pattern layer, and it can measure a location value (X−1 and Y−1 coordinates) of the electromagnetic induction input. The electromagnetic induction input detecting circuit 432 can transmit input data including a calculated location value to the control unit 440.

According to an embodiment of the present disclosure, an electronic pen integrated with a metal coil may be configured with a resonance circuit including a capacitor and an inductor. For example, the electronic pen may be configured so that an induced voltage is stored in the capacitor if a voltage is induced through a resonance circuit by an external electromagnetic field, and the induced electromagnetic field is emitted through the resonance circuit by the voltage stored in the capacitor if the externally induced electromagnetic field is removed.

If the electromagnetic field is induced by the coil included in the second pattern layer of the input unit (multi-input pad) 420 and the coil included in the electronic pen, the electromagnetic induction input detecting circuit 432 measures a voltage difference generated by the electromagnetic field and identifies an input location of the electronic pen where the voltage difference is generated.

According to an embodiment of the present disclosure, the touch input detecting circuit 433 can be electrically connected to the touch panel 411 of the touch screen 410. A location value (X−2 and Y−2 coordinates) of a touch input on the touch panel can be measured by measuring a signal transmitted from the touch panel 411 through the touch input detecting circuit 433 and by measuring a capacitance change detected from the transmitted signal. The touch input detecting circuit 433 can transmit input data including a calculated location value (X−2 and Y−2 coordinates) to the control unit 440.

The control unit 440 can process data by controlling the general operations of the electronic device and signal flows between internal components of the electronic device. The control unit 440 controls a battery to supply an electric power to the internal components. The control unit 440 can execute various application programs stored in a program area in order to perform functions according to a user setting, and may include at least one application processor (AP) or at least one communication processor (CP).

According to an embodiment of the present disclosure, the control unit 440 is electrically connected to the input detecting unit 430, and can receive input data including at least one of a location value and a pressure value detected by the multi-input pad and the touch panel of the input unit 420 and identify a user input corresponding to the input data. The control unit 440 can execute a function corresponding to the identified user input.

The control unit 440 can identify a user gesture or a touch gesture based on the input data transmitted from the touch input detecting circuit 433. The control unit 440 can detect a contact point, movement distance, movement direction, and movement speed of a touch.

The control unit 440 can identify a contact point of the electronic pen based on the input data transmitted from the electromagnetic induction input detecting circuit 432, and can identify a pressure value applied to the upper part of the input unit 420 and a location point of the pressure based on the input data transmitted from the pressure detecting circuit 431.

For example, the control unit 440 can receive at least one of a pressure value (Z-coordinate) according to a pressure change while detecting a pressure and a location value (X- and Y-coordinates) according to the pressure change from the pressure detecting circuit 431. The control unit 440 can receive a location value (X−1 and Y−1 coordinates) of an electromagnetic induction input generated according to a voltage difference from the electromagnetic induction input detecting circuit 432 while detecting the voltage difference according to an induced electromagnetic force, and can receive a location value (X−2 and Y−2 coordinates) of a touch input from the touch input detecting circuit 433.

The control unit 440 can simultaneously receive at least one signal for a pressure value (Z-coordinate) according to a pressure change, location value (X- and Y-coordinates) generated by the pressure change, location value (X−1 and Y−1 coordinates) of an electrostatic induction input, and location value (X−2 and Y−2 coordinates) of a touch input.

If the location value (X- and Y-coordinates) generated according to the pressure change, pressure value (Z-coordinate), and location value (X−2 and Y−2 coordinates) of the touch input are simultaneously received, the control unit 440 can determine a user input by synchronizing each location value and identifying location coordinates of an applied pressure.

If location value (X- and Y-coordinates) generated according to the pressure change, detected pressure value (Z-coordinate), and location value (X−1 and Y−1 coordinates) of an electrostatic induction input are simultaneously received, the control unit 440 can determine a user input by synchronizing each location value and identifying location coordinates and a pressure value of an applied pressure.

The control unit 440 can execute a function corresponding to the user input, and can control the display panel to output a screen corresponding to the execution of the function.

An input unit and an electronic device having the same according to embodiments of the present disclosure are formed in a digitizer structure such that a metallic layer for removing a magnetic flux imbalance of an electromagnetic field is used as one of two electrodes for a pressure sensor. Thus, the size and material costs of an electronic device can be limited by reducing the thickness of the input unit.

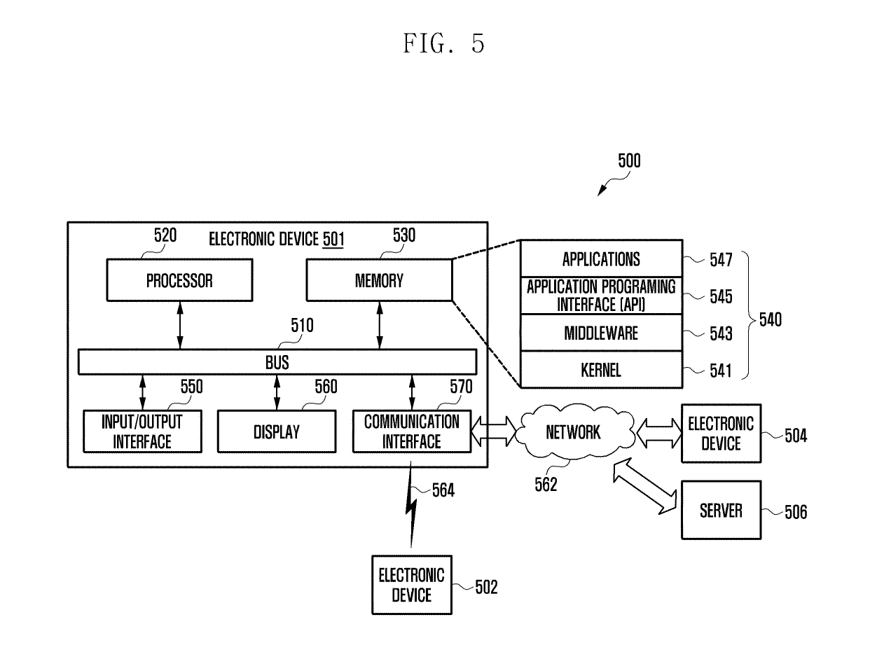

FIG. 5 illustrates a network environment including an electronic device according to an embodiment of the present disclosure.

Referring to FIG. 5, an electronic device 501 of a network environment 500 may include a bus 510, a processor 520, a memory 530, an input/output (I/O) interface 540, a display 550 and a communication interface 560.

The bus 510 may be a circuit connecting the above described components and transmitting a control message and data between the above described components.

The processor 520 may receive commands through the bus 510 from other components, such as the memory 530, the input/output interface 540, the display 550, the communication interface 560, or the communication control module, analyze the received commands, and execute calculation or data processing according to the analyzed commands. The processor 520 includes at least one a central processing unit (CPU), an application processor (AP) and an communication processor (CP).

The memory 530 may store commands or data received from the processor 520 or other components or generated by the processor 520 or other components, and may include programming modules such as a kernel 541, middleware 543, an application programming interface (API) 545, and applications 534 Each of the aforementioned programming modules may be implemented by software, firmware, hardware, or a combination of at least two thereof.

The kernel 531 may control or manage system resources, such as the bus 510, the processor 520, or the memory 530, used for executing an operation or function implemented by the remaining programming modules, such as the middleware 532, the API 533, or the applications 534, and may provide an interface for accessing individual components of the electronic device 501 from the middleware 532, the API 533, or the applications 534 to control or manage the components.

The middleware 532 may perform a relay function of allowing the API 533 or the applications 534 to communicate with the kernel 531 to exchange data. In operation requests received from the applications 534, the middleware 532 performs a control for the operation requests, such as scheduling or load balancing, by using a method of assigning a priority, by which system resources of the electronic device 501 can be used, to the applications 534.

The API 533 is an interface by which the applications 534 can control a function provided by the kernel 531 or the middleware 532 and may include at least one interface or function for a file control, a window control, image processing, or a character control.

The input/output interface 540 may transmit a command or data input from the user through an input/output device to the processor 520, the memory 530, the communication interface 560, or the display control module 570 through the bus 510. For example, the input/output interface 540 may provide data on a user's touch input through a touch screen to the processor 520, and may output a command or data received through the bus 510, from the processor 520, the memory 530, the communication interface 560, or the display control module 570 through the input/output device, such as outputting voice data processed through the processor 520 to the user through the speaker.

The display 550 may display various pieces of information to the user, such as multimedia data and text data. The display 550 may be a liquid crystal display (LCD), a light-emitting diode (LED), a microelectromechanical systems (MEMS), an electronic paper display or an active matrix organic light emitting diode (AM-OLED).

The communication interface 560 may connect communication between the electronic device 501 and the external device, such as the electronic device 504 or server 506. For example, the communication interface 560 may access a network 562 through wireless or wired communication to communicate with the external device. The wireless communication may include at least one of wireless fidelity (wifi), bluetooth (BT), near field communication (NFC), a global positioning system (GPS), and cellular communication, such as LTE, LTE-A, CDMA, WCDMA, UMTS, WiBro or GSM. The wired communication may include at least one of a universal serial bus (USB), a high definition multimedia interface (HDMI), recommended standard 232 (RS-232), and a plain old telephone service (POTS).

According to an embodiment, the network 562 may be a telecommunication network, such as a computer network, the Internet, Internet of things (IoT), and a telephone network.

According to an embodiment, the server 506 may support driving of the electronic device 501 by performing at least one of operations (or functions) implemented by the electronic device 501. For example, the server 506 may include a communication control server module 508 that may support the communication control module 570 implemented in the electronic device 501, by including at least one of components of the communication control module 570 to perform at least of operations performed by the communication control module 570.

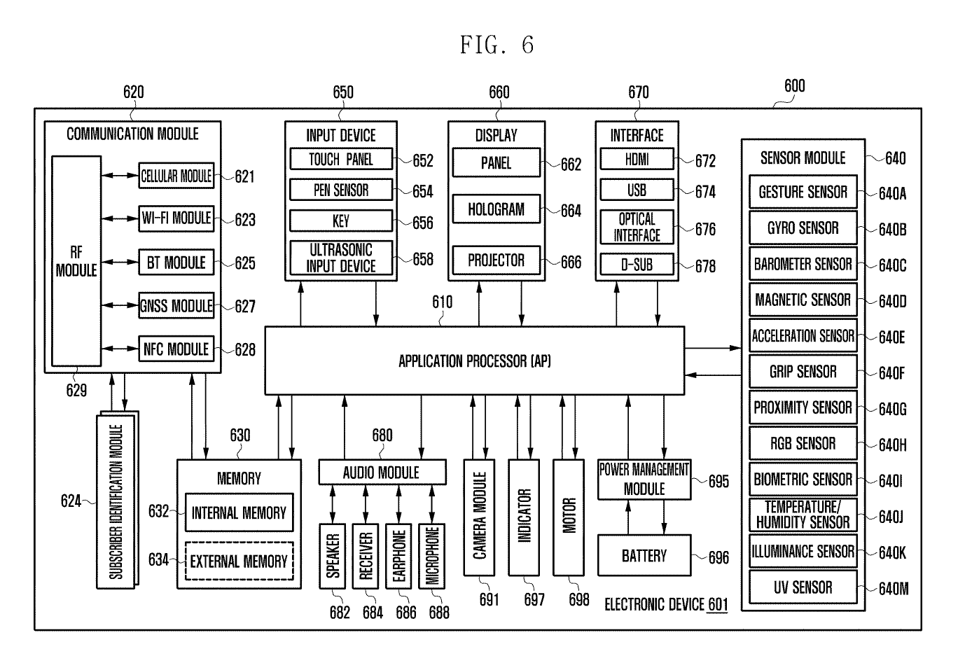

FIG. 6 illustrates an electronic device 201 according to embodiments of the present disclosure. The electronic device 601 may configure all or a part of the electronic device 501 illustrated in FIG. 5.

Referring to FIG. 6, the electronic device 601 may include one or more application processors (APs) 610, a communication module 620, a subscriber identification module (SIM) card 624, a memory 630, a sensor module 640, an input device 650, a display 660, an interface 670, an audio module 680, a camera module 691, a power managing module 695, a battery 696, an indicator 697, and a motor 698.

The AP 610 operates an operation system or an application program so as to control a plurality of hardware or software component elements connected to the AP 610 and execute various data processing and calculations including multimedia data, may be implemented by a system on chip (SoC), and may further include a graphic processing unit (GPU).

The communication module 620 may transmit/receive data in communication between different electronic devices connected to the electronic device 601 through a network. According to an embodiment, the communication module 620 may include a cellular module 621, a wifi module 623, a bluetooth (BT) module 625, a global navigation satellite system (GNSS) module 627, a near field communication (NFC) module 628, and a radio frequency (RF) module 629.

The cellular module 621 may provide a voice, a call, a video call, SMS, or an Internet service through a communication network, such as long term evolution (LTE), LTE-A, code division multiple access (CDMA), wideband CDMA (WCDMA), universal mobile telecommunications service (UMTS), WiBro, or GSM. The cellular module 621 may distinguish and authenticate electronic devices within a communication network by using the SIM card 624. According to an embodiment, the cellular module 621 may perform at least some of the functions which can be provided by the AP 610, such as some of the multimedia control functions.

Each of the wifi module 623, the BT module 625, the GNSS module 627, and the NFC module 628 may include a process for processing data transmitted/received through the corresponding module. Although the cellular module 621, the wifi module 623, the BT module 625, the GPS module 627, and the NFC module 628 are illustrated as blocks separated from each other in FIG. 6, at least two of these modules may be included in one integrated chip (IC) or one IC package according to one embodiment. For example, at least the communication processor corresponding to the cellular module 621 and the wifi processor corresponding to the wifi module 623 may be implemented by one SoC.

The SIM card 624 may include a subscriber identification module, may be inserted into a slot formed in a particular portion of the electronic device, and may include unique identification information, such as an integrated circuit card identifier (ICCID)) or subscriber information, such as an international mobile subscriber identity (IMSI).

The memory 630 may include an internal memory 632 or an external memory 634. The internal memory 632 may include at least one of a volatile memory (e.g., a dynamic random access memory (DRAM), a static RAM (SRAM), or a synchronous dynamic RAM (SDRAM)), and a non-volatile memory (e.g., a one-time programmable read only memory (OTPROM), a programmable ROM (PROM), an erasable and programmable ROM (EPROM), an electrically erasable and programmable ROM (EEPROM), a mask ROM, a flash ROM, a NAND flash memory, or an NOR flash memory).

According to an embodiment, the internal memory 632 may be a solid state drive (SSD). The external memory 634 may further include a flash drive, such as a compact flash (CF), a secure digital (SD), a micro secure digital (Micro-SD), a mini secure digital (Mini-SD), or an extreme digital (xD) drive, or a memory stick. The external memory 634 may be functionally connected to the electronic device 601 through various interfaces, and the electronic device 601 may further include a storage device such as a hard drive.

The sensor module 640 may measure a physical quantity or detect an operation state of the electronic device 601, and convert the measured or detected information to an electronic signal. The sensor module 640 may include at least one of a gesture sensor 640A, a gyro sensor 640B, an atmospheric pressure (i.e., barometer) sensor 640C, a magnetic sensor 640D, an acceleration sensor 640E, a grip sensor 640F, a proximity sensor 640G a color sensor 640H (e.g., red, green, and blue (RGB) sensor) 640H, a biometric sensor 640I, a temperature/humidity sensor 640J, an illuminance sensor 640K, and an ultra violet (UV) sensor 640M. Additionally or alternatively, the sensor module 640 may include a E-nose sensor, an electromyography (EMG) sensor, an electroencephalogram (EEG) sensor, an electrocardiogram (ECG) sensor, an infrared (IR) sensor, an iris sensor, or a fingerprint sensor. The sensor module 640 may further include a control circuit for controlling one or more sensors included in the sensor module 640.

The input device 650 may include a touch panel 652, a (digital) pen sensor 654, a key 656, and an ultrasonic input device 658. For example, the touch panel 652 may recognize a touch input in at least one type of a capacitive, resistive, infrared, and acoustic wave type, and may further include a control circuit. In the capacitive type, the touch panel 652 can recognize proximity as well as a direct touch. The touch panel 652 may further include a tactile layer that provides a tactile reaction to the user.

The (digital) pen sensor 654 may be implemented using a method identical or similar to a method of receiving a touch input of the user, or using a separate recognition sheet. The key 656 may include a physical button, an optical key, or a key pad. The ultrasonic input device 658 can detect an acoustic wave by a microphone 688 of the electronic device 601 through an input means generating an ultrasonic signal to identify data and can perform wireless recognition. According to an embodiment, the electronic device 601 may receive a user input from an external device connected to the electronic device 601 by using the communication module 620.

The display 660 may include a panel 662, a hologram device 664, and a projector 666. The panel 662 may be a liquid crystal display (LCD) or an active matrix organic light emitting diode (AM-OLED), may be implemented to be flexible, transparent, or wearable, and may be configured by the touch panel 652 and one module. The hologram device 264 may display a stereoscopic image in the air by using interference of light. The projector 666 may project light on a screen to display an image. For example, the screen may be located inside or outside the electronic device 601. According to an embodiment, the display 660 may further include a control circuit for controlling the panel 662, the hologram device 664, or the projector 666.

The interface 670 may include a high-definition multimedia interface (HDMI) 672, a universal serial bus (USB) 674, an optical interface 676, or a d-subminiature (D-sub) 678. The interface 670 may be included in the communication interface 560 illustrated in FIG. 5, and may include a mobile high-definition link (MHL) interface, a secure digital (SD) card/multi-media card (MMC), or an infrared data association (IrDA) standard interface.

The audio module 680 may bi-directionally convert a sound and an electronic signal. At least some components of the audio module 680 may be included in the input/output interface 540 illustrated in FIG. 5. The audio module 680 may process sound information input or output through a speaker 682, a receiver 684, an earphone 686, or the microphone 688.

The camera module 691 can photograph a still image and a video. According to an embodiment, the camera module 691 may include one or more image sensors, such as a front sensor or a back sensor, an image signal processor (ISP) or a flash, such as an LED or xenon lamp.

The power managing module 695 may manage power of the electronic device 601 and may include a power management integrated circuit (PMIC), a charger integrated circuit (IC), or a battery gauge.

The battery gauge may measure a remaining quantity of the battery 696, or a voltage, a current, or a temperature during the charging. The battery 696 may store or generate electricity and supply power to the electronic device 601 by using the stored or generated electricity, and may include a rechargeable battery or a solar battery.

The indicator 697 may show particular statuses of the electronic device 601 or a part of the hardware, such as a booting, message, or charging status. The motor 698 may convert an electrical signal to a mechanical vibration.

The electronic device 601 may include a processing unit for supporting a module TV, which may process media data according to a standard of digital multimedia broadcasting (DMB), digital video broadcasting (DVB), or media flow.

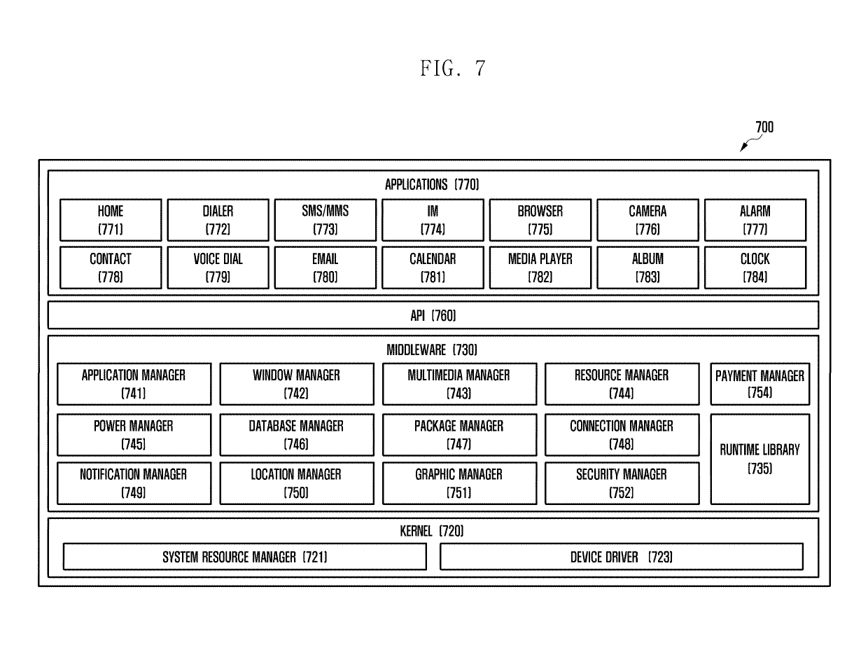

FIG. 7 is a block diagram of a programming module 700 according to an embodiment of the present disclosure. Referring to FIG. 7, the programming module 700 may include a kernel 720, a middleware 730, an application programming interface (API) 760, and applications 770.

At least some of the programming module 700 may be formed of software, firmware, hardware, or a combination of at least two of software, firmware, and hardware. The programming module 700 may be executed in the hardware to include an operating system (OS) controlling resources related to the electronic device or various applications 770 driving on the OS. For example, the OS may be android, iOS, windows, symbian, tizen, or bada.

The kernel 720 may include a system resource manager 721 or a device driver 722. The system resource manager 721 may include a process manager, a memory manager, and a file system manager. The system resource manager 721 may perform a system resource control, allocation, or recall. The device driver 723 may include a display driver, a camera driver, a Bluetooth driver, a shared memory driver, a USB driver, a keypad driver, a wifi driver, an audio driver, and an inter-process communication (IPC) driver. The middleware 730 may include a plurality of modules prepared in advance to provide a function required in common by the applications 770, and may provide a function through the API 760 to allow the applications 770 to efficiently use limited system resources within the electronic device. The middleware 700 may include at least one of a runtime library 735, an application manager 741, a window manager 742, a multimedia manager 743, a resource manager 744, a power manager 745, a database manager 746, a package manager 747, a connectivity manager 748, a notification manager 749, a location manager 750, a graphic manager 751, and a security manager 752.

The runtime library 735 may include a library module used by a compiler to add a new function through a programming language while at least one of the applications 770 is executed, and may execute input and output, management of a memory, or a function associated with an arithmetic function.

The application manager 741 may manage a life cycle of at least one of the applications 770. The window manager 742 may manage GUI resources used on the screen. The multimedia manager 743 may detect a format required for reproducing various media files and perform an encoding or a decoding of a media file by using a codec suitable for the corresponding format. The resource manager 744 may manage resources such as a source code, a memory, or a storage space of at least one of the applications 770.

The power manager 745 may operate together with a basic input/output system (BIOS) to manage a battery or power and provide power information required for the operation. The database manager 746 may manage generation, search, or change of a database to be used by at least one of the applications 770. The package manager 747 may manage an installation or an update of an application distributed in a form of a package file.

The connectivity manager 748 may manage a wireless connection such as wifi or bluetooth. The notification manager 749 may display or notify a user of an event such as an arrival message, an appointment, or a proximity alarm, in a manner that does not disturb the user. The location manager 750 may manage location information of the electronic device. The graphic manager 751 may manage a graphic effect provided to the user or a user interface related to the graphic effect. The security manager 752 may provide a general security function required for a system security or a user authentication. According to an embodiment, when the electronic device has a call function, the middleware 730 may further include a telephony manager for managing a voice of the electronic device or a video call function.

The middleware 730 may generate a new middleware module through a combination of various functions of the aforementioned internal component modules and use the generated new middleware module, may provide a module specified for each type of operating system to provide a differentiated function, and may dynamically delete some of the conventional components or add new components. Accordingly, some of the components described in the embodiment of the present disclosure may be omitted or replaced with other components having different names but performing similar functions, and other components may be further included.

The API 760 is a set of API programming functions, and may be provided with a different configuration according to an operating system. For example, in android or iOS, a single API set may be provided for each platform. In tizen, two or more API sets may be provided.

The applications 770 may include a preloaded application or a third party application. Specifically, the applications 770 may include home 771, dialer 772, SMS/MMS 773, instant message (IM) 774, browser 775, camera 776, alarm 777, contact 778, voice dial 779, email 780, calendar 781, media player 782, album 783, and clock 784 applications. At least some of the programming module 700 may be implemented by a command stored in a computer-readable storage medium. When the command is executed by one or more processors, the one or more processors may perform a function corresponding to the command. The computer-readable storage medium may be the memory 260. At least some of the programming module 700 may be implemented by the processor 510, and may include a module, a program, a routine, sets of instructions, or a process for performing one or more functions.

In embodiments of the present disclosure, the application module 734 may include applications that are related to SMS/MMS, email, calendar, alarm, health care, such as for measuring blood sugar level, or a workout application, and environment information including atmospheric pressure, humidity, or temperature.

The application module may be an application related to exchanging information between the electronic device 701 and the external electronic devices (e.g., an electronic device 504). The information exchange-related application may include a notification relay application for transmitting specific information to an external electronic device or a device management application for managing external electronic devices.

For example, the notification relay application may include a function for transmitting notification information, created by the other applications of the electronic device 701 (e.g., short message service/multimedia messaging service (SMS/MMS), email, health care, and environment information application), to an external electronic. In addition, the notification relay application may receive notification information from an external electronic device 704 and provide the notification information to the user. The device management application can install, delete, or update part of the functions of an external electronic device communicating with the electronic device, e.g., turning on/off all or part of the components of the external electronic device, and adjusting the brightness or the display resolution of the display of the external electronic device, applications operated in the external electronic device, or services such as call or messaging service from the external electronic device.

Each of the elements/units of the electronic device according to the present disclosure may be implemented with one or more components, and may be referred to by different names according to types of electronic devices. The electronic device according to the present disclosure may include at least one above-described element, and may also be modified in such a manner as to remove part of the elements or include new elements. In addition, the electronic device according to the present disclosure may also be modified such that parts of the elements are integrated into one entity that performs their original functions.

At least some of the programming module may be implemented by a command stored in a computer-readable storage medium. When the command is executed by one or more processors, the one or more processors may perform a function corresponding to the command. The computer-readable storage medium may be the memory. At least some of the programming module may be implemented by the processor and may include a module, a program, a routine, sets of instructions, or a process for performing one or more functions.

In the present disclosure, the terminology ‘module’ refers to a ‘unit’ including hardware, software, firmware or a combination thereof, and is interchangeable with ‘unit,’ ‘logic,’ ‘logical block,’ ‘component,’ or ‘circuit’. A ‘module’ may be the least identifiable unit or part of an integrated component, may also be the least unit or part thereof that can perform one or more functions of the module, and may be implemented through mechanical or electronic modes. For example, ‘modules’ according to embodiments of the present disclosure may be implemented with at least one of an application specific integrated circuit (ASIC) chip, a field-programmable gate array (FPGAs) and a programmable-logic device that can perform functions that are known or will be developed in the future.

While the present disclosure has been shown and described with reference to embodiments thereof, it will be understood by those skilled in the art that various changes in form and details may be made therein without departing from the spirit and scope of the present disclosure as defined by the appended claims and their equivalents.

What is claimed is:

1. An electronic device comprising:
a first pattern layer formed of electrodes for detecting a first direction input value;
a conductive layer disposed above the first pattern layer and separated from the first pattern layer; and
a second pattern layer disposed above the conductive layer and separated from the conductive layer, the second pattern layer including patterns for detecting a second direction input value and a third direction input value,
wherein the conductive layer is configured to absorb a portion of a magnetic flux generated by one of the electrodes or the second pattern layer, for detecting a distance change from the first pattern layer.

2. The electronic device of claim 1, wherein the first pattern layer and the second pattern layer are electrically connected to an input detecting unit which calculates at least one of the first direction input value, the second direction input value, and the third direction input value from a signal transmitted from the first pattern layer or the second pattern layer, and
wherein the conductive layer is electrically connected to the input detecting unit and ground.

3. The electronic device of claim 1, further comprising:
a dielectric layer stacked between the first pattern layer and the conductive layer and configured to partially expose faced surfaces between the first pattern layer and the conductive layer; and
a magnetic layer stacked between the conductive layer and the second pattern layer and configured to increase a magnetic flux intensity of the second pattern layer.

4. The electronic device of claim 1, wherein the dielectric layer includes an air gap or a material having a different dielectric constant from the first pattern layer or the conductive layer.

5. The electronic device of claim 1, wherein the first direction input value, the second direction input value, and the third direction input value correspond respectively to a Z-axis coordinate, an X-axis coordinate, and a Y-axis coordinate.

6. The electronic device of claim 1, wherein the first pattern layer and the conductive layer are configured to detect a pressure change from a distance change between the two layers if the conductive layer is elastically deformed by an external pressure, and
wherein the conductive layer and the second pattern layer are configured to detect an electromagnetic induction input according to a voltage change generated by an induced electromagnetic force.

7. The electronic device of claim 1, further comprising:
a touch screen including a display panel stacked on the second pattern layer and a touch panel stacked on the display panel for detecting a touch input;
at least one input detecting unit electrically connected to the first pattern layer, the second pattern layer, and the conductive layer, and configured to measure a signal transmitted from the first pattern layer and the second pattern layer for calculating input data; and
a control unit configured to identify a user input based on the input data transmitted from the input detecting unit and to perform a function corresponding to the user input.

8. The electronic device of claim 7, wherein the at least one input detecting unit comprises at least one of:
a pressure detecting circuit electrically connected to the first pattern layer and configured to measure the first direction input value based on the signal transmitted from the first pattern layer;
an electrostatic induction input detecting unit electrically connected to the second pattern layer and configured to measure the second direction input value and the third direction input value based on the signal transmitted from the second pattern layer; and
a touch input detecting circuit electrically connected to the touch panel and configured to measure the second direction input value and the third direction input value based on a signal transmitted from the touch panel.

9. The electronic device of claim 7, wherein the at least one input detecting unit is configured to detect a pressure change by applying a reference voltage to the conductive layer and measuring a signal transmitted from the first pattern layer, or to detect an electromagnetic induction input by measuring the signal transmitted from the second pattern layer, in order to detect the first direction input value or the second direction and second direction input value.

10. The electronic device of claim 8, wherein the pressure detecting circuit and the electrostatic induction input detecting circuit are configured in an input detecting unit or in separate input detecting units.

11. The electronic device of claim 7, wherein the control unit is further configured to individually or simultaneously receive the first direction input value transmitted from the first pattern layer, the second direction input value and the third direction input value transmitted from the second pattern layer, and the second direction input value and the third direction input value transmitted from the touch panel.

12. The electronic device of claim 7, wherein the control unit is further configured to synchronize the second direction input value and the third direction input value transmitted from the second pattern layer with the second direction input value and the third direction input value transmitted from the touch panel, identify location coordinates and a pressure value according to a user's touch input or an electromagnetic induction input based on the synchronized second direction input value and the third direction input value, and identify the first direction input value.

13. The electronic device of claim 7, wherein the control unit is further configured to identify at least one a pressure value according to input data detected by the first pattern layer and the conductive layer, a location value according to an electromagnetic induction input detected by the conductive layer and the second pattern layer, and a location value according to a touch input detected by the touch panel.

14. An electronic device comprising:
a first pattern layer formed of electrodes for detecting a first direction input value;
at least one second pattern layer disposed above the conductive layer and separated from the conductive layer, the second pattern layer configured to detect a second direction input value and a third direction input value;
a conductive layer disposed between the first pattern layer and the at least one second pattern layer; and
a first input detecting unit electrically connected to the first pattern layer and a second input detecting unit electrically connected to the at least one second pattern layer.

15. The electronic device of claim 14, wherein the first input detecting unit supplies a reference voltage to the conductive layer for detecting the first direction input value, and detects a pressure change by measuring a signal transmitted from the first pattern layer; and
wherein the second input detecting unit supplies a reference value to the conductive layer for detecting the second direction input value and the third direction input value, and detects an electromagnetic induction input by measuring a signal transmitted from the at least one second pattern layer.

16. The electronic device of claim 14, further comprising:
a touch detecting layer configured to detect a touch input on the first pattern layer; and
a third input detecting unit electrically connected to the touch detecting layer and configured to measure the second direction input value and the third direction input value according to a touch input signal transmitted from the touch detecting layer.
